(19) United States
(12) Patent Application Publication
(10) Pub. No.: US 2013/0157419 A1
(43) Pub. Date: Jun. 20, 2013

(54) METHOD OF MANUFACTURING SEMICONDUCTOR DEVICE

(71) Applicant: NITTO DENKO CORPORATION, Ibaraki-shi (JP)

(72) Inventors: Yusaku Shimizu, Ibaraki-shi (JP); Shinya Akizuki, Ibaraki-shi (JP); Takashi Oda, Ibaraki-shi (JP); Eiji Toyoda, Ibaraki-shi (JP); Takeshi Matsumura, Ibaraki-shi (JP)

(73) Assignee: NITTO DENKO CORPORATION, Ibaraki-shi (JP)

(21) Appl. No.: 13/718,821

(22) Filed: Dec. 18, 2012

(30) Foreign Application Priority Data
Dec. 19, 2011 (JP) 2011-277335

(51) Int. Cl. H01L 21/56

(52) U.S. Cl. CPC H01L 21/56
USPC 438/127

(57) ABSTRACT

The objective of the present invention is to provide a method of manufacturing a semiconductor device having less contamination of a semiconductor chip and good productivity. The present invention is a method of manufacturing a semiconductor device having a semiconductor chip, with the steps of preparing a plurality of semiconductor chips, preparing a resin sheet having a thermosetting resin layer, arranging the plurality of semiconductor chips on the thermosetting resin layer, arranging a cover film on the plurality of semiconductor chips, and embedding the plurality of semiconductor chips in the thermosetting resin layer by a pressure applied through the arranged cover film, in which the contact angle of the cover film to water is 90° or less.

### BACKGROUND OF THE INVENTION

1. Field of the Invention

The present invention relates to a method of manufacturing a semiconductor device.

2. Description of the Related Art

In recent years, the miniaturization of semiconductor devices and the refinement of wiring have increasingly advanced, more I/O pads and vias have to be arranged in a narrow region of a semiconductor chip (the overlapping region of a semiconductor chip when the semiconductor chip is being viewed in a planar view), and at the same time the pin density has increased. In addition, a large number of terminals are formed in the semiconductor chip region of a BGA (Ball Grid Array) package, and the region where other elements can be formed is limited. Therefore, a method is pursued of drawing wiring from the terminals to the outside of the semiconductor chip region on the substrate of the semiconductor package.

Under such circumstances, if the miniaturization of semiconductor devices and the refinement of wiring progress independently, productivity decreases due to an increase in the length and/or number of manufacturing lines, complexity of the manufacturing procedure, etc., and it also becomes difficult to meet the requirement of lowering the cost.

In order to meet the requirement of lowering the cost, a method has been proposed of arranging a plurality of individualized chips on a support and simultaneously sealing with a resin to form a package. For example, a method has been described in U.S. Pat. No. 7,202,107 of arranging a plurality of individualized chips on a heat-sensitive adhesive that is formed on a support, forming a plastic common carrier to cover the chips and the heat-sensitive adhesive, and then peeling the common carrier in which the chips are embedded by heating and the heat-sensitive adhesive.

### SUMMARY OF THE INVENTION

Because the heat-sensitive adhesive and the common carrier have to be peeled eventually in the method of manufacturing a semiconductor device described in U.S. Pat. No. 7,202,107, residue of the heat-sensitive adhesive may remain on the common carrier, outgas components of the heat-sensitive adhesive may remain on the common carrier as impurities, time to clean the residue and the impurities may be required, etc., and therefore productivity may decrease. In addition, the heat-sensitive adhesive in the method of manufacturing a semiconductor device described in U.S. Pat. No. 7,202,107 is used to temporarily fix the chips and then it is peeled eventually. Productivity can be improved more if these steps can be omitted.

The objective of the present invention is to provide a method of manufacturing a semiconductor device having less contamination of a semiconductor chip and good productivity.

The present inventors found that the following configuration may be adopted to solve the above-described problems.

The present invention is a method of manufacturing a semiconductor device having a semiconductor chip, having a step A of preparing a plurality of semiconductor chips, a step B of preparing a resin sheet having a thermosetting resin layer, a step C of arranging the plurality of semiconductor chips on the thermosetting resin layer, and a step D of arranging a cover film on the plurality of semiconductor chips and embedding the plurality of semiconductor chips in the thermosetting resin layer by a pressure applied through the arranged cover film, and in which the contact angle of the cover film to water is 90° or less.

According to the method of manufacturing a semiconductor device of the present invention, a plurality of semiconductor chips are arranged on a thermosetting resin layer (step C), and then the plurality of semiconductor chips are embedded in the thermosetting resin layer (step D). Therefore, the thermosetting resin layer can be used as a sealing material to seal the semiconductor chips. Because the semiconductor chips are embedded in the thermosetting resin layer after they are arranged on it, a sheet to temporarily fix the semiconductor chips is not necessary. A step of peeling the sheet to temporarily fix the semiconductor chips is not necessary either. As a result, the production process can be simplified and the production cost can be decreased. Because the semiconductor chips are embedded in the thermosetting resin layer, it is not necessary to paste a sheet for temporary tacking to the semiconductor chips and to peel it from them. As a result, the contamination of the semiconductor chips can be suppressed.

Step D of embedding is a step of embedding the plurality of semiconductor chips in the thermosetting resin layer by a pressure applied through a cover film that is arranged on the plurality of semiconductor chips, and the contact angle of the cover film to water is 90° or less. In general, the more hydrophobic it is, the smaller the surface energy becomes and the smaller the friction becomes, and the more hydrophilic it is, the larger the surface energy becomes and the larger the friction becomes. Because the contact angle of the cover film to water is 90° or less and the hydrophilicity is high with the above-described configuration, the friction force between the cover film and the semiconductor chips becomes large, and the position deviation of both the cover film and the semiconductor chips in step D of embedding can be decreased. As a result, position deviation of the semiconductor chips can be suppressed during embedding. In the present invention, the contact angle to water is regulated as an index of slippage of the surface of the cover film.

The present invention is a method of manufacturing a semiconductor device having a semiconductor chip, having a step A of preparing a semiconductor chip, a step B of preparing a resin sheet having a thermosetting resin layer, and a step D of embedding the plurality of semiconductor chips in the thermosetting resin layer.

According to the method of manufacturing a semiconductor device of the present invention, a plurality of semiconductor chips are embedded in the thermosetting resin layer (step D). Therefore, the thermosetting resin layer can be used as a sealing material to seal the semiconductor chips. Because the semiconductor chips are embedded directly in the thermosetting resin layer, a step of temporarily fixing the semiconductor chips and a sheet to temporarily fix the semiconductor chips are not necessary. As a result, the production process can be simplified and the production cost can be decreased. Because the semiconductor chips are embedded directly in the thermosetting resin layer, it is not necessary to paste a sheet for temporary tacking to the semiconductor chips and to peel it from them. As a result, the contamination of the semiconductor chips can be suppressed.

According to the present invention, a method of manufacturing a semiconductor device having less contamination of a semiconductor chip and good productivity can be provided.

### BRIEF DESCRIPTION OF THE DRAWINGS

FIG. 1 is a schematic sectional view showing a method of manufacturing a semiconductor device according to one embodiment of the present invention;

FIG. 2 is a schematic sectional view showing a method of manufacturing a semiconductor device according to one embodiment of the present invention;

FIG. 3 is a schematic sectional view showing a method of manufacturing a semiconductor device according to one embodiment of the present invention;

FIG. 4 is a schematic sectional view showing a method of manufacturing a semiconductor device according to one embodiment of the present invention;

FIG. 5 is a schematic sectional view showing a method of manufacturing a semiconductor device according to one embodiment of the present invention;

FIG. 6 is a schematic sectional view showing a method of manufacturing a semiconductor device according to one embodiment of the present invention;

FIG. 7 is a schematic sectional view showing a method of manufacturing a semiconductor device according to one embodiment of the present invention;

FIG. 8 is a schematic sectional view showing a method of manufacturing a semiconductor device according to one embodiment of the present invention;

FIG. 9 is a schematic sectional view showing a method of manufacturing a semiconductor device according to a second embodiment of the present invention;

FIG. 10 is a schematic sectional view showing a method of manufacturing a semiconductor device according to a third embodiment of the present invention;

FIG. 11 is a schematic sectional view showing a method of manufacturing a semiconductor device according to a fourth embodiment of the present invention; and

FIG. 12 is a schematic sectional view showing a method of manufacturing a semiconductor device according to the fourth embodiment of the present invention.

### DESCRIPTION OF THE REFERENCE CHARACTERS

1 Thermosetting Resin Layer
2 Support
5 Semiconductor Chip
5a Circuit Forming Surface
6 Conductive Member
10 Resin Sheet
12 Cover Film
14 Film for Semiconductor Backside

### DETAILED DESCRIPTION OF THE PREFERRED EMBODIMENTS

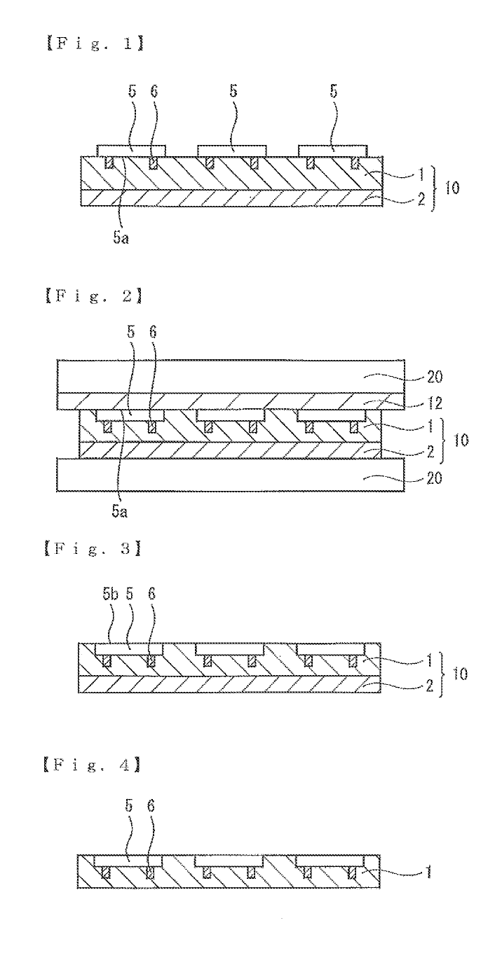

One example of an embodiment of the present invention is explained below by referring to the drawings. FIGS. 1 to 8 are schematic sectional views showing a method of manufacturing a semiconductor device according to one embodiment of the present invention. First, the method of manufacturing a semiconductor device is explained. Then, the semiconductor device that is obtained from the manufacturing method is explained.

The method of manufacturing a semiconductor device according to the present embodiment is a manufacturing method of a semiconductor device having a semiconductor chip, and has at least a step A of preparing a semiconductor chip (a semiconductor chip preparing step), a step B of preparing a resin sheet having a thermosetting resin layer (a resin sheet preparing step), a step C of arranging a plurality of semiconductor chips on the thermosetting resin layer (a semiconductor chip arranging step), and a step D of embedding the plurality of semiconductor chips in the thermosetting resin layer (a semiconductor chip embedding step).

### [Semiconductor Chip Preparing Step]

In the semiconductor chip preparing step (step A), a semiconductor chip 5 is prepared in which a conductive member 6 is formed on a circuit forming surface 5a (refer to FIG. 1). A semiconductor wafer in which a circuit is formed on the surface is diced and individualized to produce the semiconductor chip 5 with a conventionally known method. The shape at planar view of the semiconductor chip 5 may be changed depending on the objective semiconductor device, and it may be a square or a rectangle in which the length of one side is independently selected in a range of 1 to 15 mm.

The thickness of the semiconductor chip 5 may be changed depending on the size of the objective semiconductor device. It is 30 to 725 μm for example, and preferably 50 to 450 μm.

The conductive member 6 is formed on the circuit forming surface 5a of the semiconductor chip 5. The conductive member 6 is not particularly limited. However, examples include a bump, a pin, and a lead. The material of the conductive member 6 is not particularly limited. However, examples include solders (alloy) such as a tin-lead based metal, a tin-silver based metal, a tin-silver-copper based metal, a tin-zinc based metal, and a tin-zinc-bismuth based metal, a gold based metal, and a copper based metal. The height of the conductive member 6 is determined depending on its use, and it is generally about 5 to 10 μm. The height of the individual conductive members 6 on the circuit forming surface 5a of the semiconductor chip 5 maybe the same or different.

### [Resin Sheet Preparing Step]

In the resin sheet preparing step (step B), a resin sheet 10 is prepared in which a thermosetting resin layer 1 is formed on a support (refer to FIG. 1).

### (Support)

The support 2 forms a strong base of the resin sheet 10. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinyl acetate copolymer; an ionomer resin; an ethylene (meth) acrylic acid copolymer; an ethylene (meth) acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; wholly aromatic polyamides; polyphenylsulfide; aramid (paper); glass; glass cloth; a fluorine resin; polyvinyl chloride; polyvinylidene chloride; a cellulose resin; a silicone resin; glass; metal (foil); and paper. Among these, a material having heat resistance such as polycarbonate, glass, and metal (a copper foil, etc.) is preferable for a support property during heating. (Meth) acrylic acid refers to an acrylic acid and/or a methacrylic acid, and every occurrence of (meth) has the same meaning throughout the present invention.

Further, the material of the support 2 includes a polymer such as a cross-linked body of the above resins. When the support 2 is made from the above plastic, the above plastic film may be also used unstretched, or maybe also used after a monoaxial or a biaxial stretching treatment is performed depending on necessity.

A known surface treatment such as a chemical or physical treatment such as a chromate treatment, ozone exposure, flame exposure, high voltage electric exposure, and an ionized ultraviolet treatment, and a coating treatment by an undercoating agent can be performed on the surface of support 2 in order to improve adhesiveness, holding properties, etc. with the adjacent layer.

The same type or different type of base material can be appropriately selected and used as the support 2, and a base material in which a plurality of base material types are blended can be used depending on necessity. Further, a vapor-deposited layer of a conductive substance composed of a metal, an alloy, an oxide thereof, etc. and having a thickness of about 30 to 500 angstrom can be provided on the support 2 in order to give an antistatic function to the support 2. The support 2 may be a single layer or a multi-layer support of two or more types of base materials.

The thickness of the support 2 can be set appropriately without special limitation. However, it is about 5 to 200 μm, for example.

### (Thermosetting Resin Layer)

The thermosetting resin layer 1 according to the present embodiment has a function of filling a space on the circuit forming surface 5a side (the lower side of the circuit forming surface 5a in FIG. 1) and at the same time sealing the semiconductor chip 5. An example of the constituting material of the thermosetting resin layer 1 is a material in which a thermoplastic resin and a thermosetting resin are used together. Or, a thermosetting resin can be used alone.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor chip.

The acrylic resin is not limited to any special kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any special kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins maybe used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin maybe any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the connection reliability of the semiconductor device can be improved.

Regarding the blend ratio between the epoxy resin and the phenol resin, for example, the phenol resin is blended with the epoxy resin in such a manner that the equivalents of hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of this range, a curing reaction therebetween does not advance sufficiently such that properties of the cured epoxy resin easily deteriorate.

The thermal curing-accelerating catalyst of the epoxy resin and the phenol resin is not particularly limited, and a known thermal curing-accelerating catalyst can be appropriately selected and used. The thermal curing-accelerating catalyst may be used either alone or in combination of two or more types. Examples of the thermal curing-accelerating catalyst include an amine based curing accelerator, a phosphorus based curing accelerator, an imidazole based curing accelerator, a boron based curing accelerator, and a phosphorus-boron based curing accelerator.

An inorganic filler may be appropriately incorporated into the thermosetting resin layer 1. The incorporation of the inorganic filler makes it possible to confer electric conductance to the sheet, improve the thermal conductivity thereof, and adjust the elasticity.

Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used.

The average particle size of the inorganic filler is preferably 0.1 to 30 μm, and more preferably 0.5 to 25 μm. In the present invention, inorganic fillers having different average particle sizes can be combined and used together. The average particle size is obtained by a laser diffraction/scattering particle size distribution analyzer (LA-910 manufactured by HORIBA, Ltd.).

The compounded amount of the inorganic filler is preferably 100 to 1400 parts by weight to 100 parts by weight of the organic resin component. It is especially preferably 230 to 900 parts by weight. When the compounded amount of the inorganic filler is 100 parts by weight or more, the heat resistance and the strength improve. When it is 1400 parts by weight or less, the fluidity can be secured. In this manner, a decrease of the tackiness and the embedding property can be prevented.

Other additives besides the inorganic filler can be appropriately compounded in the thermosetting resin layer 1 as necessary. Examples of other additives include a flame retardant, a silane coupling agent, an ion trapping agent, a pigment such as carbon black. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These maybe used alone or in combination of two or more thereof. An elastomer component can be added as an additive for adjusting the viscosity to improve the viscosity during curing at high temperature. The elastomer component is not particularly limited as long as it can thicken the resin. However, examples include various acrylic copolymers such as polyacrylic ester; an elastomer having a styrene skeleton such as a polystyrene-polyisobutylene copolymer and a styrene acrylate copolymer; and a rubber copolymer such as a butadiene rubber, a styrene-butadiene rubber (SBR), an ethylene-vinyl acetate copolymer (EVA), an isoprene rubber, and acrylonitrile rubber.

The viscosity of the thermosetting resin layer at 120° C. is preferably 100 to 10,000 Pa·s, and more preferably 500 to 3,000 Pa·s. When the viscosity is 100 Pa·s or more, a large deformation of the surface shape during thermal curing can be suppressed. When it is 10,000 Pa·s or less, the fluidity of the resin becoming poor and the edge face of the parts not being sufficiently filled can be suppressed.

The thickness (a total thickness for the case of a plurality of layers) of the thermosetting resin layer 1 is not particularly limited. However, it is preferably 100 μm or more and 1,000 μm or less considering the strength of the resin after curing and the filling property between conductive members 6. The thickness of the thermosetting resin layer 1 can be appropriately set considering the height of the conductive members 6.

### (Method of Producing the Resin Sheet)

The thermosetting resin layer 1 is laminated on the support 2 to obtain the resin sheet according to the present embodiment.

Examples of the method of forming the support 2 include a calendering film-forming method, a casting method in an organic solvent, an inflation extruding method in a closed system, a T-die extruding method, a co-extruding method, and a dry laminating method.

An example of the method of forming the thermosetting resin layer 1 includes a method having the steps of applying an adhesive composition solution that is a constituting material of the thermosetting resin layer 1 on a release film to form a coating layer and then drying the coating layer.

The method of applying the adhesive composition solution is not particularly limited. However, examples include a comma coating method, a fountain coating method, and a gravure coating method. The thickness of the application may be appropriately set so that the final thickness of the thermosetting resin layer 1 that can be obtained by drying the coating layer is 10 to 100 μm.

The release film is not particularly limited. However, an example includes a film in which a release coating layer such as a silicone layer is formed on the surface of the release film that is pasted to the thermosetting resin layer 1. Examples of a base of the release film include paper such as glassine paper and a resin film consisting of polyethylene, polypropylene, polyester, etc.

Dry air is blown on the coating layer to dry the coating layer. Examples of the method of blowing the dry air include a method of blowing the dry air in a direction parallel to the transporting direction of the release film and a method of blowing the dry air in the direction perpendicular to the surface of the coating layer. The wind speed of the dry air is not particularly limited. However, it is normally 5 to 20 m/min, and preferably 5 to 15 m/min. When the flow of the dry air is 5 m/min or more, the coating layer is prevented from being dried insufficiently. When the flow of the dry air is 20 m/min or less, the concentration of the organic solvent in vicinity of the surface of the coating layer becomes uniform and the evaporation of the organic solvent can be uniform. As a result, the thermosetting resin layer 1 having a uniform surface condition can be formed.

The drying time is appropriately set according to the applied thickness of the adhesive composition solution; it is normally 1 to 5 min, and preferably 2 to 4 min. When the drying time is 1 min or more, the curing reaction not proceeding sufficiently and the amount of uncured components and the amount of remaining solvent becoming large can be suppressed. As a result, generation of out-gassing and voids in the post process can be prevented. When it is 5 min or less, excessive progress of the curing reaction can be suppressed. As a result, a decrease of fluidity and a decrease of the embedding property of the conductive members of the semiconductor wafer can be prevented.

The drying temperature is not particularly limited. However, it is normally 70 to 160° C. In the present embodiment, the drying temperature is preferably increased in stages as the drying time passes. Specifically, it is set in a range of 70° C. to 100° C. in the initial stage of drying (1 min or less of drying), and it is set in a range of 100° C. to 160° C. in the latter stage of drying (more than 1 min and 5 min or less). In this manner, the generation of pin holes on the surface of the coating layer can be prevented when the drying temperature is rapidly increased immediately after the coating.

Then, the thermosetting resin layer 1 is transferred onto the support 2 (refer to FIG. 1). The transfer can be performed by press-bonding. The pasting temperature is preferably 40 to 80° C., and more preferably 50 to 70° C. The pasting pressure is preferably 0.1 to 0.6 MPa, and more preferably 0.2 to 0.5 MPa.

The release film may be peeled after the thermosetting resin layer 1 is pasted onto the support 2 or it may be used as a protective film of the resin sheet 10 and may be peeled when it is arranged onto the thermosetting resin layer of the semiconductor chip. In this manner, the resin sheet 10 according to the present embodiment can be manufactured.

The adhesive composition solution may be directly applied onto the support 2 and then the coating film may be dried to form the thermosetting resin layer 1 under the drying conditions. In this manner, the resin sheet 10 can be also manufactured.

### [Semiconductor Chip Arranging Step]

In the semiconductor chip arranging step (step C), a plurality of semiconductor chips 5 are arranged on the thermosetting resin layer 1 so that the thermosetting resin layer 1 and the circuit forming surface 5a of the semiconductor chips are facing each other (refer to FIG. 1). A known apparatus such as a flip-chip bonder and a die bonder can be used to arrange the semiconductor chips 5.

The layout and the number of the semiconductor chips 5 that are arranged can be appropriately set depending on the shape and the size of the resin sheet 10, the production volume of the objective semiconductor device, etc. For example, they can be arranged in a matrix having a plurality of rows and a plurality of columns.

When the plurality of the semiconductor chips 5 are arranged onto the thermosetting resin layer 1, the conductive members 6 contact at least the thermosetting resin layer 1. In particular, the circuit forming surface 5a preferably contacts the thermosetting resin layer 1. When the conductive members 6 contact at least the thermosetting resin layer 1, the semiconductor chips 5 can be fixed to the thermosetting resin layer 1.

### [Semiconductor Chip Embedding Step]

In the semiconductor chip embedding step (step D), the plurality of semiconductor chips 5 are embedded in the thermosetting resin layer 1 by pressure applied through a cover film 12 that is arranged on the plurality of semiconductor chips 5 (refer to FIGS. 2 and 3). A press molding machine or a roll molding machine is used and pressure is applied from both sides of the resin sheet 10 for the embedding. A method of embedding can be adopted in which the cover film 12 is arranged on the plurality of the semiconductor chips 5 in advance and then pressure is applied from both sides of the resin sheet 10 (pressure is applied by a metal mold 20 for example). A method of embedding can be also adopted in which the cover film 12 is arranged on the side of the press molding machine or the roll molding machine, and the cover film 12 is arranged on the plurality of the semiconductor chips 5 while a pressure is applied. In this manner, a surface 5b (a backside 5b) is exposed that is opposite from the circuit forming surface 5a of the semiconductor chip 5, and the semiconductor chips 5 are embedded in the thermosetting resin layer 1. The embedding temperature is preferably 60 to 150° C., and more preferably 80 to 120° C. The embedding pressure is preferably 0.02 to 3 MPa, and more preferably 0.05 to 1 MPa.

### (Cover Film)

The cover film 12 is not particularly limited. However, examples include paper such as glassine paper and a resin film consisting of polyethylene, polypropylene, polyester, etc. For preventing adhesive residue of the thermosetting resin layer 1 from contaminating the backside of the semiconductor chip, the surface (the surface that contacts the thermosetting resin layer 1 and the semiconductor chips 5) of the cover film 12 can be treated with a traditional surface treatment such as a plasma treatment, an embossing treatment, and a sandblasting treatment.

The contact angle of the cover film 12 to water is 90° or less, and it is preferably 80° or less. The smaller the contact angle is, the better it is. However, it maybe 45° or more or 60° or more. Because the contact angle of the cover film 12 to water is 90° or less and the slippage of the surface of the cover film 12 is low, the friction force between the cover film 12 and the semiconductor chips 5 (the backside 5b of the semiconductor chips 5) becomes large and the position deviation of both the cover film and the semiconductor chips in the embedding step can be decreased. As a result, the position deviation of the semiconductor chips 5 can be suppressed during embedding.

### [Thermal Curing Step]

Then, the thermosetting resin layer 1 is heated and cured in the thermal curing step. The heating temperature in the thermal curing step is preferably 90 to 200° C., and more preferably 120 to 175° C. The heating time is preferably 30 to 240 min., and more preferably 60 to 180 min.

The change of the distance between the semiconductor chips before and after curing of the thermosetting resin layer is preferably within 20 μm, and more preferably within 10 μm when the semiconductor chips are arranged so that the distance between the semiconductor chips 5 becomes 5000 μm in the semiconductor chip arranging step. The distance between the semiconductor chips is referred to as the distance between adjacent semiconductor chips.

### [Support Peeling Step]

Then, the support 2 is peeled from the thermosetting resin layer 1 in the support peeling step (refer to FIG. 4). The peeling can be performed with a conventionally known peeling apparatus.

### [Film for Semiconductor Backside Pasting Step]

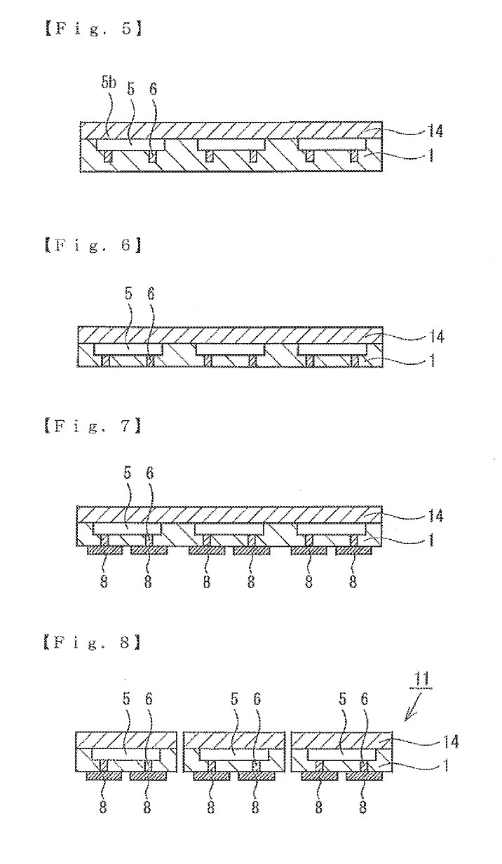

In addition, the present embodiment preferably includes a film for a semiconductor backside pasting step. A film 14 for a semiconductor backside is pasted on to the backside 5b of the semiconductor chips 5 in the film for semiconductor backside pasting step (refer to FIG. 5).

A film for a semiconductor backside (the film 14 for a semiconductor backside in the present embodiment) has a function of protecting a semiconductor element when it is formed on the backside (the backside 5b in the present embodiment) of the semiconductor element (the semiconductor chips 5 in the present embodiment). The backside of the semiconductor element means the surface that is opposite from the surface where the circuit is formed.

### (Film for Semiconductor Backside)

The film 14 for a semiconductor backside according to the present embodiment has a shape of a film. The film 14 for a semiconductor backside is normally uncured (including semi-cured) as a product, and it is thermally cured after it is pasted to a semiconductor wafer or a semiconductor element.

The film for a semiconductor backside is preferably formed from at least a thermosetting resin, and more preferably from at least a thermosetting resin and a thermoplastic resin. When it is formed from at least a thermosetting resin, the film for a semiconductor backside can effectively exhibit a function as an adhesive layer.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, a polyamide resin such as 6-nylon and 6,6-nylon, a phenoxy resin, an acrylic resin, a saturated polyester resin such as PET (polyethylene terephthalate) and PBT (polybutylene terephthalate), a polyamideimide resin, and a fluororesin. The thermoplastic resins may be used either alone or in combination of two or more types. Among these thermoplastic resins, an acrylic resin is especially preferable because it has fewer ionic impurities and good heat resistance, and the reliability of a semiconductor element can be secured.

The acrylic resin is not particularly limited. However, an example includes a polymer having acrylic acid having a straight chain or a branched alkyl group of 30 carbon atoms or fewer (preferably 4 to 18 carbon atoms, more preferably 6 to 10 carbon atoms, and further preferably 8 or 9 carbon atoms), or one or two or more types of methacrylic ester as components. The acrylic resin of the present invention is interpreted in a broad sense including a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers (monomers other than acrylic acid having an alkyl group of 30 or fewer carbon atoms, and methacrylic alkylester) forming the acrylic resin are not particularly limited. However, examples include a carboxyl group-containing monomer such as acrylic acid, methacrylic acid, carboxyethylacrylate, carboxypentylacrylate, itaconic acid, maleic acid, fumaric acid, and crotonic acid; an anhydride monomer such as maleic anhydride and itaconic anhydride; a hydroxyl group-containing monomer such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methyl acrylate; a sulfonate group-containing monomer such as styrenesulfonate, arylsulfonate, 2-(meth) acrylamide-2-methylpropanesulfonate, (meth)acrylamidepropanesulfonate, sulfopropyl(meth)acrylate, and (meth)acryloyloxynaphthalenesulfonate; and a phosphate group-containing monomer such as 2-hydroxyethylacryloylphosphate.

Examples of the thermosetting resin include an epoxy resin, a phenol resin, an amino resin, an unsaturated polyester resin, a polyurethane resin, a silicone resin, and a thermosetting polyimide resin. The thermosetting resins may be used either alone or in combination of two or more types. An epoxy resin having fewer ionic impurities that erode the semiconductor element is especially preferable as the thermosetting resin. A phenol resin can be suitably used as a curing agent of the epoxy resin.

The epoxy resin is not particularly limited. However, examples include a bifunctional epoxy resin and a polyfunctional epoxy resin such as a bisphenol A-type epoxy resin, a bisphenol F-type epoxy resin, a bisphenol S-type epoxy resin, a brominated bisphenol A-type epoxy resin, a hydrogenated bisphenol A-type epoxy resin, a bisphenol AF-type epoxy resin, a biphenyl-type epoxy resin, a naphthalene-type epoxy resin, a fluorene-type epoxy resin, a phenol novolak-type epoxy resin, an orthocresol novolak-type epoxy resin, a trishydroxyphenylmethane-type epoxy resin, and a tetraphenylolethane-type epoxy resin; and an epoxy resin such as a hydantoin-type epoxy resin, and a trisglycidyl isocyanurate-type epoxy resin.

Among these epoxy resins, a novolak-type epoxy resin, a biphenyl-type epoxy resin, a trishydroxyphenylmethane-type epoxy resin, and a tetraphenylolethane-type epoxy resin are especially preferable. These epoxy resins are rich in reactivity to a phenol resin as a curing agent, and have excellent heat resistance, etc.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

Regarding the blend ratio between the epoxy resin and the phenol resin, for example, the phenol resin is blended with the epoxy resin in such a manner that the equivalents of hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of this range, a curing reaction therebetween does not advance sufficiently such that properties of the cured epoxy resin easily deteriorate.

The content of the thermosetting resin is preferably 5% by weight or more and 90% by weight or less to the entire resin component in the film for a semiconductor backside, more preferably 10% by weight or more and 85% by weight or less, and further preferably 15% by weight or more and 80% by weight or less.

The thermal curing accelerating catalyst of the epoxy resin and the phenol resin is not particularly limited, and any known thermal curing accelerating catalysts can be appropriately selected and used. The thermal curing accelerating catalyst may be used either alone or in combination of two or more types.

The ratio of the thermal curing accelerating catalyst to the entire amount of the resin component is preferably 0.008 to 0.25% by weight, more preferably 0.0083 to 0.23% by weight, and further preferably 0.0087 to 0.22% by weight. When the ratio of the thermal curing accelerating catalyst is 0.01% by weight or more, the thermosetting resin can be cured suitably. When the ratio of the thermal curing accelerating catalyst is 0.25% by weight or less, advancement of the curing reaction when the resin is stored for an extended period of time can be suppressed.

The film for a semiconductor backside may be a single layer or a laminated film in which a plurality of layers are laminated. When the film for a semiconductor backside is a laminated film, the ratio of the thermal curing accelerating catalyst is 0.01 to 0.25% by weight to the amount of the resin component in the entire laminated film.

The film for a semiconductor backside is suitably formed from a resin composition containing an epoxy resin and a phenol resin or a resin composition containing an epoxy resin, a phenol resin, and an acrylic resin. The reliability of a semiconductor element can be secured because these resins have few ionic impurities and good heat resistance.

It is important that the film 14 for a semiconductor backside has tackiness (adhesion) to the backside 5b (the circuit non-forming surface) of the semiconductor chip 5. The film 14 for a semiconductor backside can be formed from a resin composition containing an epoxy resin as the thermosetting resin for example. Because the film 14 for a semiconductor backside is crosslinked to some extent in advance, a polyfunctional compound that reacts with functional groups, etc. of the ends of the polymer molecular chain is preferably added as a crosslinking agent when producing the film. In this manner, the adhesion characteristics at high temperature can be improved and the heat resistance can be improved.

The adhering strength (23° C., peeling angle: 180 degree, peeling speed: 300 mm/min) of the film for a semiconductor backside to the semiconductor wafer (the semiconductor chip) is preferably 0.5 N/20 mm to 15 N/20 mm, and more preferably 0.7 N/20 mm to 10 N/20 mm. When it is 0.5 N/20 mm or more, the film is pasted to the semiconductor wafer or the semiconductor chip with excellent adhesion, and the generation of bubbling, etc. can be prevented.

The crosslinking agent is not particularly limited, and known crosslinking agents can be used. Specific examples include an isocyanate based crosslinking agent, an epoxy based crosslinking agent, a melamine based crosslinking agent, a peroxide based crosslinking agent, a urea based crosslinking agent, a metal alkoxide based crosslinking agent, a metal chelate based crosslinking agent, a metal salt based crosslinking agent, a carbodiimide based crosslinking agent, an oxazoline based crosslinking agent, an aziridine based crosslinking agent, and an amine based crosslinking agent. An isocyanate based crosslinking agent and an epoxy based crosslinking agent are preferable. The crosslinking agent may be used either alone or in combination of two or more types.

The used amount of the crosslinking agent is not particularly limited, and it can be appropriately selected depending on the extent of crosslinking. The used amount of the crosslinking agent is normally preferably 7 parts by weight or less (0.05 to 7 parts by weight for example) to 100 parts by weight of the polymer component (in particular, a polymer having a functional group at the ends of the molecular chain). When the used amount of the crosslinking agent is more than 7 parts by weight to 100 parts by weight of the polymer component, it is not preferable because the adhering strength decreases. For improving the cohesive strength, the used amount of the crosslinking agent is preferably 0.05 parts by weight or more to 100 parts by weight of the polymer component.

In the present invention, the crosslinking treatment can be performed by irradiation with an electron beam and an ultraviolet ray instead of using the crosslinking agent or together with the crosslinking agent.

The film for a semiconductor backside is preferably colored. In this manner, an excellent marking property and outer appearance can be exhibited, and a semiconductor device with a value-added outer appearance can be produced. Because the colored film for a semiconductor backside has an excellent marking property, the non-circuit surface of a semiconductor element or the semiconductor device in which the semiconductor element is used can be marked with various marking methods such as a printing method and a laser marking method through the film for a semiconductor backside to add various information such as character information and graphic information. In particular, the color is controlled for visual recognition of information (character information, graphic information, etc.) and for marking the film with excellent visibility.

When the film 14 for a semiconductor backside is colored, the form of coloring is not particularly limited. The film for a semiconductor backside may be a film of a single layer in which a coloring agent is added. It may be a laminated film in which a resin layer that is formed from at least a thermosetting resin and a coloring agent layer are laminated. When the film 14 for a semiconductor backside is a laminated film of the resin layer and the coloring agent layer, the film 14 for a semiconductor backside preferably has a laminated form of a resin layer/a coloring layer/a resin layer. In this case, two resin layers on both sides of the coloring layer may be resin layers having the same composition or resin layers having a different compositions.

Other additives can be appropriately compounded in the film 14 for a semiconductor backside as necessary. Examples of other additives include a filler, a flame retardant, a silane coupling agent, an ion trapping agent, an extender, an anti-aging agent, an antioxidant, and a surfactant.

The filler may be an inorganic filler or an organic filler. However, an inorganic filler is preferable. The filler such as an inorganic filler is compounded in the film to impart conductivity to the film for a semiconductor backside, to improve the thermal conductivity, to adjust the modulus, etc. The film 14 for a semiconductor backside may be conductive or non-conductive. Examples of the inorganic filler include ceramics such as silica, clay, plaster, calcium carbonate, barium sulfate, alumina oxide, beryllium oxide, silicon carbide, and silicon nitride; metals such as aluminum, copper, silver, gold, nickel, chromium, lead, tin, zinc, palladium, and solder; alloys; and various inorganic powders consisting of carbon, etc. The filler may be used either alone or in combination of two or more types. Among these fillers, silica, especially fused silica, is preferable. The average particle size of the inorganic filler is preferably 0.1 μm to 80 μm. The average particle size of the inorganic filler can be measured with a laser diffraction/scattering particle size distribution analyzer.

The compounded amount of the filler (especially the inorganic filler) is preferably 80 parts by weight or less (0 to 80 parts by weight) to 100 parts by weight of the organic resin component, and especially preferably 0 to 70 parts by weight.

Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These maybe used alone or in combination of two or more thereof.

The thermosetting resin such as an epoxy resin is mixed with the thermoplastic resin such as an acrylic resin, a solvent, and other additives as necessary to prepare a resin composition, and then the resin composition is formed into a film layer with a traditional method to form the film 14 for a semiconductor backside. Specifically, a film layer (an adhesive layer) as the film for a semiconductor backside can be formed with a method of applying the resin composition on an appropriate separator such as release paper to form a resin layer or an adhesive layer and drying the layer. The resin composition may be a solution or a dispersion.

When the film 14 for a semiconductor backside is formed from a resin composition containing the thermosetting resin such as an epoxy resin, the thermosetting resin of the film for a semiconductor backside is uncured or partially cured before it is applied to the semiconductor wafer.

The thickness (the total thickness in the case of a laminated film) of the film 14 for a semiconductor backside is not particularly limited, and can be appropriately selected between 2 μm to 200 μm. The thickness is preferably 4 μm to 160 μm, more preferably 6 μm to 100 μm, and especially preferably 10 μm to 80 μm.

The light transmittance of visible light (wavelength: 400 nm to 800 nm) (the visible light transmittance) of the film 14 for a semiconductor backside is not particularly limited. However, it is preferably 20% or less (0 to 20%) , more preferably 10% or less (0 to 10%) , and especially preferably 5% or less (0 to 5%) . When the visible light transmittance is 20% or less, a harmful effect of visible light passing through to the semiconductor element can be decreased. The visible light transmittance (%) can be controlled by the type and the content of the resin component of the film 14 for a semiconductor backside, the type and the content of the coloring agent such as pigment and dye, the content of the inorganic filler, etc.

### [Face Side Processing Step]

In the face side processing step, the surface where the film 14 for a semiconductor backside of the thermosetting resin layer 1 is not pasted is ground (refer to FIG. 6). A conventionally known back grinding tape is pasted on the film 14 for a semiconductor backside first, and this step can be performed using a conventionally known backside grinding apparatus to expose the conductive member 6.

In the film for a semiconductor backside pasting step, the case of pasting the film 14 for a semiconductor backside is explained. However, a back grinding tape integrated-type film for a semiconductor backside, in which a film for a semiconductor backside is laminated on a back grinding tape, may be pasted to the backside 5b of the semiconductor chip 5. In this case, a step of pasting the back grinding tape can be omitted.

### [Rewire Forming Step]

In the rewire forming step, a rewire 8 that connects to the exposed conductive member 6 is formed on the thermosetting resin layer (refer to FIG. 7).

A metal seed layer is formed on the exposed conductive member 6 and the thermosetting resin layer 1 using a known method such as a vacuum deposition method, and then the rewire 8 can be formed using a known method such as a semi-additive method.

Then, an insulating layer such as polyimide and polybenzoxazole (PBO) may be formed onto the rewire 8 and the thermosetting resin layer 1.

### [Bump Forming Step]

Then, a bumping treatment may be performed in which the bumps are formed on the formed rewire 8 (not shown in the drawings). The bumping treatment can be performed with a known method such as solder ball and solder plating. The materials of the conductive member that are explained in the semiconductor chip preparing step can be suitably used as the material of the bumps.

### [Dicing Step]

Last, a laminated body having the thermosetting resin layer 1, the semiconductor chip 5, the film 14 for a semiconductor backside, the rewire 8, etc. is diced (refer to FIG. 8) to obtain a semiconductor device 11 in which the wiring is drawn out to the outside of the chip region. The dicing is performed with the laminated body being fixed by a conventionally known dicing sheet. The alignment of the cut position may be performed by image recognition using infrared rays (IR).

In the present step, a cutting method, a so-called fullcut, in which cutting is performed up to the dicing sheet can be adopted. The dicing apparatus used in the present step is not particularly limited, and a conventionally known method can be used.

When expanding of the laminated body is performed after the dicing step, the expanding can be performed using a conventionally known expanding apparatus. The expanding apparatus has a donut-shaped outer ring that can push the laminated film downward through a dicing ring, and an inner ring having a smaller diameter than that of the outer ring that supports the laminated film. Damage of the semiconductor device 11 caused by the adjacent semiconductor devices 11 contacting each other can be prevented by the expanding step.

According to the method of manufacturing a semiconductor device of the present embodiment, the plurality of semiconductor chips 5 are arranged on the thermosetting resin layer 1 (step C), and then the plurality of semiconductor chips 5 are embedded in the thermosetting resin layer 1 (step D). Therefore, the thermosetting resin layer 1 can be used as a sealing material to seal the semiconductor chips 5. Because the semiconductor chips 5 are embedded in the thermosetting resin layer 1 after they are arranged on it, a sheet to temporarily fix the semiconductor chips is not necessary. A step of peeling the sheet to temporarily fix the semiconductor chips is not necessary either. As a result, the production process can be simplified and the production cost can be decreased. Because the semiconductor chips 5 are embedded in the thermosetting resin layer 1, it is not necessary to paste a sheet for temporary tacking to the semiconductor chips and to peel it from them. As a result, contamination of the semiconductor chips can be suppressed.

### Second Embodiment

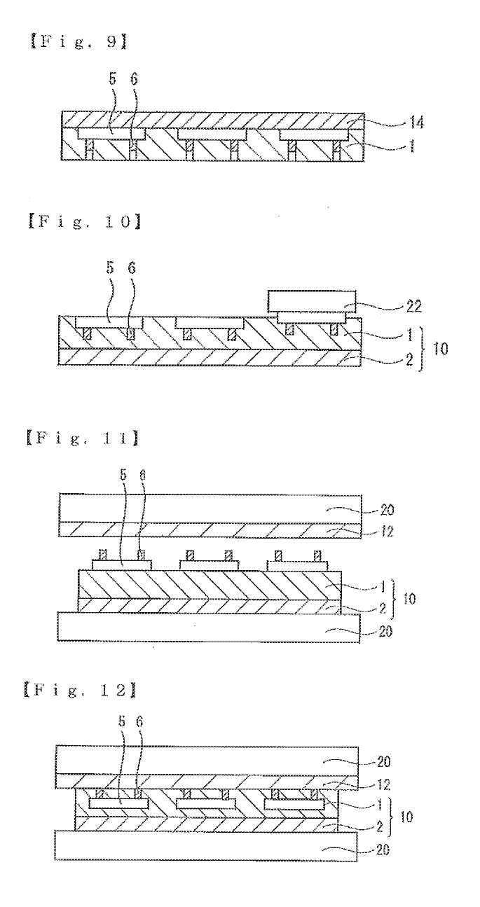

The case is explained in the above-described first embodiment in which the conductive member 6 is exposed by the face side processing step, in which the surface is ground where the film 14 for a semiconductor backside of the thermosetting resin layer 1 is not pasted to (refer to FIG. 6). However, the method of exposing the conductive member 6 is not limited to this in the present invention, and the conductive member can be also exposed by a laser processing step from the thermosetting resin layer 1 side (a laser processing step). In this case, the laser processing step is performed instead of the face side processing step. FIG. 9 is a schematic sectional view showing a method of manufacturing a semiconductor device according to a second embodiment of the present invention. As shown in FIG. 9, laser processing is performed from the thermosetting resin layer 1 side to expose the conductive member 6 in the second embodiment. A carbon dioxide gas laser, a YAG laser, an excimer laser, etc. can be used as the laser. After the laser processing, a step of forming the rewire 8 that connects to the exposed conductive member 6 is performed (the rewire forming step).

### Third Embodiment

The case is explained in the above-described first embodiment in which the plurality of semiconductor chips 5 are arranged on the thermosetting resin layer 1 and then embedded; that is, the semiconductor chip arranging step (step A) is performed, and then the semiconductor chip embedding step (step B) is performed. However, the method of embedding the semiconductor chips in the thermosetting resin layer is not limited to this in the present invention, and the semiconductor chips can be directly embedded in the thermosetting resin layer one by one. FIG. 10 is a schematic sectional view showing a method of manufacturing a semiconductor device according to a third embodiment of the present invention. As shown in FIG. 10, the semiconductor chips 5 can be directly embedded in the thermosetting resin layer 1 one by one in the third embodiment. A conventionally known flip-chip bonder 22 can be used for embedding. As the embedding conditions, the pressure is preferably 0.01 to 3 MPa, and more preferably 0.05 to 1 MPa. The temperature is preferably 80 to 280° C., and more preferably 180 to 220° C.

According to the method of manufacturing a semiconductor device of the present embodiment, the thermosetting resin layer 1 can be used as a sealing material to seal the semiconductor chips 5. Because the semiconductor chips 5 are directly embedded in the thermosetting resin layer 1, a step of temporarily fixing the semiconductor chips and a sheet to temporarily fix the semiconductor chips are not necessary. As a result, the production process can be simplified and the production cost can be decreased. Because the semiconductor chips 5 are directly embedded in the thermosetting resin layer 1, it is not necessary to paste a sheet for temporary tacking to the semiconductor chips and to peel it from them. As a result, contamination of the semiconductor chip can be suppressed.

### Fourth Embodiment

The case is explained in the above-described first embodiment in which a plurality of semiconductor chips 5 are arranged on the thermosetting resin layer 1 so that the thermosetting resin layer 1 and the circuit forming surface 5a of the semiconductor chips 5 are facing each other in the semiconductor chip arranging step (step C) (refer to FIG. 1). However, the arrangement of the semiconductor chips is not limited to this in the present invention, and a plurality of semiconductor chips may be arranged on the thermosetting resin layer so that the thermosetting resin layer and the surface opposite to the circuit forming surface of the semiconductor chips are facing each other. FIGS. 11 and 12 are schematic sectional views showing a method of manufacturing a semiconductor device according to a fourth embodiment of the present invention. As shown in FIG. 11, a plurality of semiconductor chips 5 are arranged on the thermosetting resin layer 1 so that the thermosetting resin layer 1 and the surface opposite to the circuit forming surface 5a of the semiconductor chips 5 are facing each other. Then, a pressure is applied through the cover film 12 arranged on the plurality of the semiconductor chips 5 to embed the plurality of the semiconductor chips 5 in the thermosetting resin layer 1.

### Fifth Embodiment

The case is explained in the above-described first embodiment in which the resin sheet 10 is used in which the thermosetting resin layer 1 is laminated on the support 2. However, the resin sheet is not limited to this in the present invention as long as it has a thermosetting resin layer. The resin sheet of the present invention may consist of only a thermosetting resin layer.

### (Semiconductor Device)

As shown in FIG. 8, the semiconductor device 11 has the semiconductor chips 5 embedded in the thermosetting resin layer 1, and has the rewire 8 that is formed on the thermosetting resin layer 1 and that is connected to the conductive member 6 of the semiconductor chips 5.

### EXAMPLES

### <Production of the Resin Sheet>

100 parts by weight of an epoxy resin (YSLV-80XY manufactured by Tohto Kasei Co., Ltd., epoxy equivalent 200, softening point 80° C.), 105 parts by weight of a phenol curing agent (MEH7851SS manufactured by Meiwa Plastic Industries, Ltd., hydroxyl group equivalent 203, softening point 67° C.), 2198 parts by weight of fused silica (FB-9454 manufactured by Denki Kagaku Kogyo Kabushiki Kaisha, average particle size 20 μm), 2.5 parts by weight of an imidazole based compound (2PHZ-PW manufactured by Shikoku Chemicals Corporation) as a curing accelerator, and 90 parts by weight of a polystyrene-polyisobutylene based copolymer (SIBSTAR072T manufactured by Kaneka Corporation) as an additive for adjusting the viscosity were mixed using a kneading machine, and the mixture was press-rolled with a press machine to produce a resin sheet A (thickness 1000 μm).

The viscosity of the resin sheet A at 120° C. was 2000 Pa˜s. The measurement was performed at 1 Hz using an ARES rheometer manufactured by TA Instruments.

### <Cover Film>

A release treatment was performed on a PET film (thickness 50 μm) produced by extruding to obtain a cover film A.

An embossing treatment was performed on a polyolefin film (thickness 50 μm) produced by extruding to obtain a cover film B.

### (Measurement of the Contact Angle)

The contact angle of the produced cover film to water was measured with a θ/2 method by dripping pure water onto the film. The result is shown in Table 1.

TABLE 1

| | Cover Film A | Cover Film B |
|---|---|---|
| Contact Angle (°) to Water | 100 | 80 |

### (Evaluation of the Semiconductor Chip Embedding Step)

The evaluation of embedding the semiconductor chip was performed using the produced resin sheet and the cover films. The evaluation was performed with the case of using the resin sheet A and the cover film A being Comparative Example 1 and the case of using the resin sheet A and the cover film B being Example 1. The evaluation was performed also with the case of embedding the chips into the resin sheet A one by one being Example 2.

Specifically, 16 semiconductor chips were arranged in 4 columns and 4 rows on the thermosetting resin layer so that the thermosetting resin layer of the resin sheet and the circuit forming surface of the semiconductor chip were facing each other for the evaluation of Comparative Example 1 and Example 1. The distance between the semiconductor chips was 5000 μm. The size of the semiconductor chips was 5 mm square. The semiconductor chips were arranged using a die bonder SPA-300 manufactured by Shinkawa Ltd. at a table temperature of 70° C., a die bonding pressure of 1 kg, and a pressure applying time of 1 sec. Then, the semiconductor chips were embedded. Specifically, a cover film was arranged in an instantaneous vacuum laminating apparatus VS008-1515 manufactured by Mikado Technos Co., Ltd., and a pressure was applied through the cover film to embed a plurality of the semiconductor chips in the thermosetting resin layer. The set conditions of the apparatus were, vacuum: 20 Torr; table temperature: 90° C.; pressure: 0.05 MPa; and pressure applying time: 1 min. After that, the thermosetting resin layer was cured in conditions of, temperature: 120° C.; and heating time: 3 hr. The presence of the adhesive residue on the backside of the semiconductor chip after the thermosetting resin layer was cured was observed with a microscope. The result is shown in Table 2. The case was evaluated as “no chip shift” in which a change of the distance between chips before and after curing of the thermosetting resin layer was 20 μm or less, and the case was evaluated as “chip shift” in which the change was larger than 20 μm. The result is shown in Table 2.

For the evaluation of Example 2, semiconductor chips having a size of 5 mm square were embedded using a flip-chip bonder FB30T-M manufactured by Panasonic Corporation at an embedding speed of 50 μm/sec, a load of 1 kg, and an embedding time 10 sec. The distance between the semiconductor chips was 5000 μm. After that, the thermosetting resin layer was cured in conditions of, temperature: 120° C.; and heating time: 3 hr. The case was evaluated as “no chip shift” in which a change of the distance between chips before and after curing of the thermosetting resin layer was 20 μm or less, and the case was evaluated as “chip shift” in which the change was larger than 20 μm. The result is shown in Table 2.

TABLE 2

| | | | Comparative |
|---|---|---|---|
| | Example 1 | Example 2 | Example 1 |
| Chip Shift | No | No | Yes |
| Adhesive Residue | No | — | No |
| After Curing | | | |

What is claimed is:

1. A method of manufacturing a semiconductor device having a plurality of semiconductor chips, comprising the steps of:
preparing the plurality of semiconductor chips,
preparing a resin sheet having a thermosetting resin layer,
arranging the plurality of semiconductor chips on the thermosetting resin layer, and
arranging a cover film on the plurality of semiconductor chips and embedding the plurality of semiconductor chips in the thermosetting resin layer by a pressure applied through the arranged cover film, wherein
a contact angle of the arranged cover film to water is 90° or less.

2. A method of manufacturing a semiconductor device having a plurality of semiconductor chips, comprising the steps of:
preparing the plurality of semiconductor chips,
preparing a resin sheet having a thermosetting resin layer, and
embedding the plurality of semiconductor chips in the thermosetting resin layer.
